(19) United States
(12) Patent Application Publication
(10) Pub. No.: US 2006/0284219 A1
(43) Pub. Date: Dec. 21, 2006

(54) Semiconductor integrated circuit device method of fabricating the same

(75) Inventors: Dong-Ryul Chang, Suwon-si (KR); Soo-Cheol Lee, Seoul (KR); Tae-Jung Lee, Yongin-si (KR); Hyeon-Cheol Kim, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/441,304

(22) Filed: May 25, 2006

(30) Foreign Application Priority Data
Jun. 8, 2005 (KR) 10-2005-0049018

(51) Int. Cl. H01L 29/76

(52) U.S. Cl. 257/288

(57) ABSTRACT

A semiconductor integrated circuit device is provided. The semiconductor integrated circuit device includes a semiconductor substrate, a transistor having a gate interconnection that extends in one direction on the semiconductor substrate and source/drain regions aligned in the gate interconnection and formed in the semiconductor substrate, and a diffusion-preventing metallic pattern extending on the gate interconnection in the same direction as the gate interconnection and which prevents ions from being diffused into the semiconductor substrate.

This application claims priority from Korean Patent Application No. 10-2005-0049018 filed on Jun. 8, 2005, in the Korean Intellectual Property Office, the disclosure of which is hereby incorporated by reference herein in its entirety.

### BACKGROUND OF THE INVENTION

1. Field of the Invention

The present invention relates to a semiconductor integrated circuit device and a method of fabricating the same, and more particularly, to a semiconductor integrated circuit device having improved operating characteristics and a method of fabricating the same.

2. Description of the Related Art

Semiconductor integrated circuit devices such as e.g., a system-on-chip (SOC), a microcontroller unit (MCU), and a display driver IC (DDI) typically include a plurality of peripheral devices such as a processor, a memory, a logic circuit, an audio and image processing circuit, and various interface circuits. Thus, the semiconductor integrated circuit devices include transistors having various driving voltages. For example, a high voltage (15-30 V) driving transistor, an intermediate voltage (4-6 V) driving transistor, and a low voltage (1-3 V) driving transistor may be included in a semiconductor integrated circuit device.

In particular, the breakdown voltage between a drain region and a semiconductor substrate of a high-voltage driving transistor should be high so that the high-voltage driving transistor operates normally even when a high voltage is applied thereto. To increase the breakdown voltage in a high voltage driving transistor, a highly doped region of the drain region and a gate interconnection should be separated a sufficient distance apart from each other. Meanwhile, to increase the depletion region, the doping concentration of the lightly doped region of the drain region and the doping concentration of the semiconductor substrate should be low. In addition, the thickness of a gate insulating layer of the high-voltage driving transistor should be larger than the thickness of a gate insulating layer of a low-voltage driving transistor.

After the high-voltage driving transistor is manufactured, a subsequent back-end process of forming a multi-layered interconnection and a multi-layered insulating layer is performed. However, during the back-end process, external ions or water penetrate into the gate insulating layer. For example, in an NMOS high-voltage driving transistor, positive ions that penetrate into a gate insulating layer cause degradation of the threshold voltage and a channel to be formed below the gate insulating layer, which in turn causes the drain off current Idoff to increase. Consequently, as the doping concentration of the lightly doped region of the drain region and the doping concentration of the semiconductor substrate are low, the high-voltage driving transistor exhibits a significant variation in its operating characteristics even from a slight penetration of external ions into the gate insulating layer.

Thus, there is a need for a semiconductor integrated circuit device having improved operating characteristics and to methods of fabricating the same.

### SUMMARY OF THE INVENTION

According to an exemplary embodiment of the present invention, a semiconductor integrated circuit device is provided. The semiconductor integrated circuit device includes a semiconductor substrate, a transistor having a gate interconnection that extends in one direction on the semiconductor substrate and source/drain regions aligned in the gate interconnection and formed in the semiconductor substrate, and a diffusion-preventing metallic pattern extending on the gate interconnection in the same direction as the gate interconnection and which prevents ions from being diffused into the semiconductor substrate.

According to another exemplary embodiment of the present invention, a method of fabricating a semiconductor integrated circuit device is provided. The method includes forming a transistor having a gate interconnection that extends in one direction on a semiconductor substrate and source/drain regions aligned in the gate interconnection and formed in the semiconductor substrate. The method further includes forming a diffusion-preventing metallic pattern extending on the gate interconnection in the same direction as the gate interconnection and which prevents ions from being diffused into the semiconductor substrate.

### BRIEF DESCRIPTION OF THE DRAWINGS

FIG. 1 is a layout diagram of a semiconductor integrated circuit device according to an exemplary embodiment of the present invention;

FIG. 2 is a cross-sectional view taken along line II-II′ of FIG. 1;

FIGS. 3A and 3B illustrate the effect of a semiconductor integrated circuit device illustrated in FIG. 1;

FIG. 4 is a layout diagram of a semiconductor integrated circuit device according to an exemplary embodiment of the present invention;

FIG. 5 is a cross-sectional view taken along line V-V′ of FIG. 4;

FIG. 6 is a layout diagram of a semiconductor integrated circuit device according to an exemplary embodiment of the present invention;

FIG. 7 is a cross-sectional view taken along line VII-VII′ of FIG. 6;

FIG. 8 is a layout diagram of a semiconductor integrated circuit device according to an exemplary embodiment of the present invention;

FIG. 9 is a layout diagram of a semiconductor integrated circuit device according to an exemplary embodiment of the present invention;

FIG. 10 is a layout diagram of a semiconductor integrated circuit device according to an exemplary embodiment of the present invention;

FIG. 11 is a layout diagram of a semiconductor integrated circuit device according to an exemplary embodiment of the present invention;

FIGS. 12A through 12D are cross-sectional views for explaining a method of fabricating a semiconductor integrated circuit device illustrated in FIG. 1; and

FIG. 13 shows the result of measuring a variation in threshold voltage by forming a diffusion-preventing metallic pattern to the same interconnection level as a first interconnection after a plurality of NMOS high-voltage driving transistors are fabricated.

### DETAILED DESCRIPTION OF THE EXEMPLARY EMBODIMENTS OF THE INVENTION

The exemplary embodiments of the present invention will now be described more fully by reference to the accompanying drawings. The present invention may, however, be embodied in many different forms and should not be construed as being limited to the exemplary embodiments set forth herein.

Here, a high voltage driving transistor indicates a transistor to which a driving voltage of about 15- about 30 V is applied and a low voltage driving transistor indicates a transistor to which a driving voltage of about 3 V or less is applied. However, it is apparent to one skilled in the art that a concrete value for the driving voltage can be readily changed by one skilled in the art.

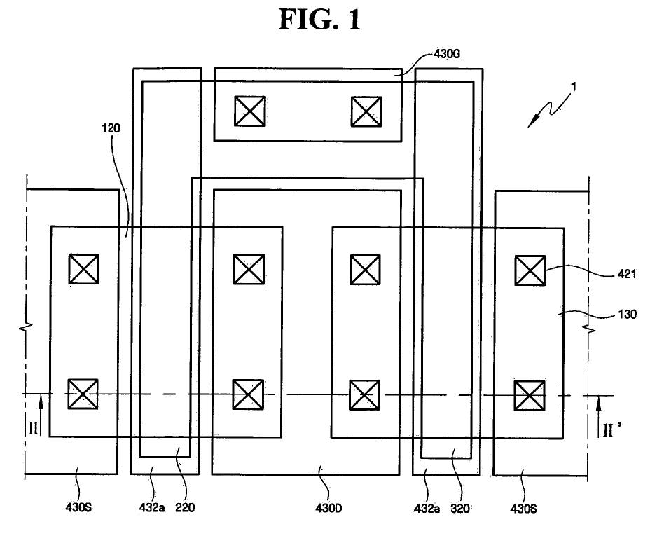

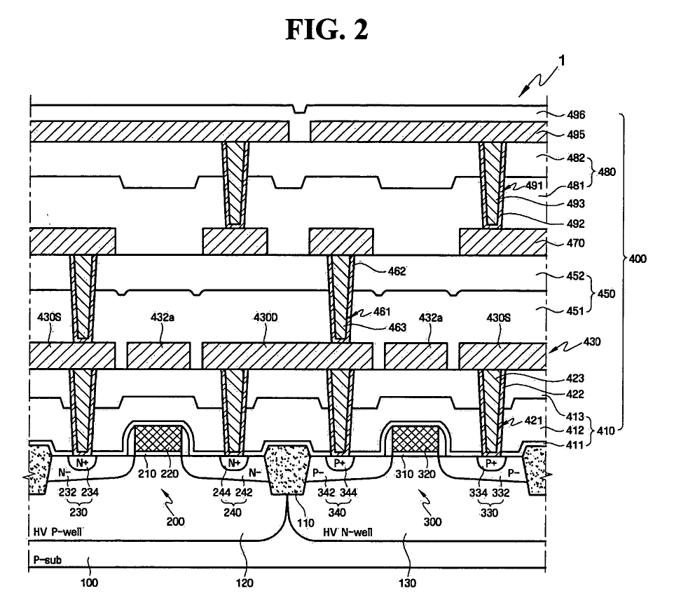

FIG. 1 is a layout diagram of a semiconductor integrated circuit device according to an exemplary embodiment of the present invention, and FIG. 2 is a cross-sectional view taken along line II-II′ of FIG. 1. While a semiconductor integrated circuit device according to the present exemplary embodiment of the invention is described with reference to an inverter of a display driver IC (DDI), the invention is not limited thereto.

Referring to FIGS. 1 and 2, a semiconductor integrated circuit device 1n includes a semiconductor substrate 100, an NMOS high voltage driving transistor 200, a PMOS high voltage driving transistor 300, and a dielectric layer structure 400.

The semiconductor substrate 100 may be a silicon substrate, a SOI (Silicon on Insulator) substrate, a gallium arsenic substrate, a silicon germanium substrate, a ceramic substrate, a quartz substrate, or a glass substrate for a display device. The semiconductor substrate 100 is usually a P-type substrate. Moreover, a P-type epitaxial layer may be grown on the semiconductor substrate 100.

A device isolation layer 110 formed on the semiconductor substrate 100 defines an active region. An isolation layer may be a shallow trench isolation (STI) or a field oxide isolation (FOX) formed by a local oxidation (LOCOS) process.

A P well 120 and an N well 130 may be formed to obtain a high voltage driving transistor in the semiconductor substrate 100. Moreover, the density of a well used in a high voltage driving transistor is lower than that of a well used in a low voltage driving transistor. For example, the density of the P well 120 and/or the N well 130 may be in a range of about 1×10¹⁵- about 1×10¹⁷ atom/cm³.

The NMOS high voltage transistor 200 includes a gate interconnection 220, a gate insulating layer 210, a source region 230, and a drain region 240.

The gate interconnection 220 is a conductive layer pattern extended in a specific direction on the semiconductor substrate 100 and is insulated from the semiconductor substrate 100 through the gate insulating layer 210. The gate insulating layer 210 is usually made of silicon oxide (SiOₓ). The thickness of a gate insulating layer of a high voltage driving transistor is larger than that of a gate insulating layer of a low voltage driving transistor. For example, the gate insulating layer 210 of the NMOS high voltage transistor 200 may have a thickness of about 200- about 400 Å and a gate insulating layer of a low voltage transistor may have a thickness of about 30- about 150 Å. In other words, the gate insulting layer of the low voltage driving transistor is thin, thereby increasing the driving speed of a semiconductor device, and the gate insulating layer 210 of the NMO high voltage transistor 200 is thick, thereby having a sufficiently high withstanding-voltage characteristic at a high voltage of about 15V or higher.

The source/drain regions 230 and 240 are aligned with both sidewalls of the gate interconnection 220. For instance, in this exemplary embodiment, the NMOS high-voltage driving transistor 200 has the source/drain regions 230 and 240 in a mask islanded double diffused drain (MIDDD) structure to be suitable for high voltage driving. That is, lightly doped regions 232 and 242 are aligned in the gate interconnection 220 and formed in the semiconductor substrate 100, and highly doped regions 234 and 244 are separated from the gate interconnection 220 by a predetermined distance and formed to a lower depth than the lightly doped regions 232 and 242. In this way, the highly doped regions 234 and 244 to which high voltages are applied should be separated from the gate interconnection 220 by a sufficient distance so that a breakdown voltage increases.

Also, the lightly doped regions 232 and 242 are lower than the concentration of a lightly doped region used in a general low-voltage driving transistor. For example, the concentration of the lightly doped regions 232 and 242 may be about 1×10¹⁴- about 1×10¹⁰ atom/cm³. In this way, if the P-well 120 and the lightly doped regions 232 and 242 are doped with low concentration, the width of the depletion region increases at the boundary of the P-well 120 and the lightly doped regions 232 and 242. Thus, since the breakdown voltage sufficiently increases, even when a high voltage is applied to the drain region 240, the low-voltage driving transistor can operate stably.

Although the source region 230 and the drain region 240 form an MIDDD structure in this exemplary embodiment of the present invention, they may also have a lightly diffused drain (LDD) structure, a mask LDD (MLDD) structure, or a lateral double-diffused MOS (LDMOS) structure as long as they are suitable for high voltage driving.

The PMOS high voltage driving transistor 300 includes a gate electrode 320, a gate insulating layer 310, a source region 330, and a drain region 340. The PMOS high voltage driving transistor 300 is complementary to the NMOS high voltage driving transistor 200 and thus an additional explanation thereof will not be given.

The insulating layer structure 400 includes an interlayer dielectric (ILD) layer 410, a contact 423, a first interconnection 430, a diffusion-preventing metallic pattern 432a, a first intermetallic insulating layer 450, a first via 463, a second interconnection 470, a second intermetallic insulating layer 480, second vias 493, a third interconnection 495, and a passivation layer 496.

The interlayer dielectric layer 410 is formed on the NMOS high voltage driving transistor 200, the PMOS high voltage driving transistor 300, and the semiconductor substrate 100. The interlayer dielectric layer 410 is formed of a low dielectric constant dielectric material. The low dielectric constant dielectric material for the interlayer dielectric layer 410 may be at least one selected from the group consisting of, for example, a flowable oxide (FOX) layer, a Tonne silazene (TOSZ) layer, a undoped silicate glass (USG) layer, a borosilicate glass (BSG) layer, a phosphosilicate glass (PSG) layer, a borophosphosilicate glass (BPSG) layer, a plasma enhanced tetraethylorthosilicate (PE-TEOS) layer, a fluoride silicate (FSG) layer, a high density plasma (HDP) layer, a plasma enhanced oxide, and a stack layer of these layers. The overall dielectric constant of an interconnection line of the semiconductor integrated circuit device 1 and a resistance-capacitance (RC) delay can be reduced.

In the exemplary embodiment shown in FIG. 1, the ILD layer 410 uses a stack layer of a PEOX layer 411, a BPSG layer 412, and a PETEOS layer 413. Here, the PEOX layer 411 is used as a buffer layer, and the BPSG layer 412 has excellent gap-fill characteristics and reduces a step difference caused by the gate interconnections 220 and 320. Since the PETEOS layer 413 is made of a material having good throughput, the ILD layer 410 can be formed to a predetermined thickness within a short period of time.

The contact 423 is formed in a predetermined region of the interlayer dielectric layer 410 to electrically connect the source/drain regions 230, 240, 330, 340, the gate electrodes 220 and 320 of the NMOS and PMOS high voltage driving transistors 200 and 300 and the first interconnection line 430. The contact 423 may be formed of a metal material such as copper, titanium, or tungsten.

In addition, a first barrier layer pattern 422 is formed around the contact 423 so that a material used in forming the contact 423 is prevented from being diffused into the ILD layer 410. The first barrier pattern 422 may be formed of Ti, TiN, Ti/TiN, Ta, TaN, Ta/TaN, or Ta/TiN.

The first interconnection 430 is formed on the ILD layer 410 and is a conductive layer pattern that is connected to the source/drain regions 230, 240, 330, and 340 of the NMOS and PMOS high-voltage driving transistors 200 and 300 and the gate interconnections 220 and 320, respectively. The first interconnection 430 includes a source voltage interconnection 430S for applying a source voltage to the source regions 230 and 330 of the NMOS and PMOS high-voltage driving transistors 200 and 300, a drain voltage interconnection 430D for applying a source voltage to the drain regions 240 and 340, and a gate voltage interconnection 430G for applying a gate voltage to the gate interconnections 220 and 320. In FIG. 1, a ground voltage is applied to the source region 230 of the NMOS high-voltage driving transistor 200, a power supply voltage is applied to the source region 330 of the PMOS high-voltage driving transistor 300, and a predetermined signal voltage is applied to the drain regions 240 and 340 of the NMOS and PMOS high-voltage driving transistors 200 and 300, respectively.

The first interconnection line 430 may be formed of aluminum to a thickness of about 5000 Å. When the first interconnection line 430 is an aluminum interconnection line, an adhesion film may be further formed of titanium/titanium nitride (Ti/TiN) between the first interconnection line 430 and the contact 423 to improve the adhesion between the first interconnection line 430 and the contact 423, and an anti-reflection coating film may be further formed of Ti, TiN, or Ti/TiN on the first interconnection line 430 to prevent a diffuse reflection of aluminum during a photolithography process.

The diffusion-preventing metallic pattern 432a is formed to the same interconnection level as the first interconnection 430. The diffusion-preventing metallic pattern 432a is formed on the gate interconnections 220 and 320 of the NMOS and PMOS high-voltage driving transistors 200 and 300 and extends in the same direction as the gate interconnections 220 and 320. In addition, the diffusion-preventing metallic pattern 432a is separated from the source voltage interconnection 430S, the drain voltage interconnection 430D, and the gate voltage interconnection 430G by a predetermined distance so that the diffusion-preventing metallic pattern 432a shown in FIG. 1 is electrically floated. The diffusion-preventing metallic pattern 432a sufficiently covers upper portions of the gate interconnections 220 and 320 so that external ions or water can be prevented from penetrating into the gate insulating layers 210 and 310.

For example, external ions or water can be included in the first and second intermetallic insulating layers 450 and 480 formed on the first interconnection 430 and the diffusion-preventing metallic pattern 432a during a fabrication process. The external ions or water are diffused and can be accumulated on the gate insulating layers 210 and 310. The external ions or water accumulated in this way may change the level of the threshold voltage and increase a drain off current Idoff. The diffusion-preventing metallic pattern 432a can prevent external ions or water from penetrating into the gate insulating layers 210 and 310, thereby maintaining the threshold voltage at a constant level and reducing the drain off current Idoff.

In addition, the diffusion-preventing metallic pattern 432a can be made of aluminum like the first interconnection 430.

The first intermetallic dielectric layer 450 is formed over the entire surface of the first interconnection 430, the diffusion-preventing metallic pattern 432a, and the interlayer dielectric layer 410. The first intermetallic dielectric layer 450 is made of a low dielectric constant dielectric material, which may be, for example, at least one selected from the group consisting of a flowable oxide (FOX) layer, a Tonne silazene (TOSZ) layer, a undoped silicate glass (USG) layer, a borosilicate glass (BSG) layer, a phosphosilicate glass (PSG) layer, a borophosphosilicate glass (BPSG) layer, a plasma enhanced tetraethylorthosilicate (PE-TEOS) layer, a fluoride silicate (FSG) layer, a high density plasma (HDP) layer, a plasma enhanced oxide, and a stack layer of these layers. Use of a low dielectric constant dielectric material as the first intermetallic dielectric layer 450 reduces the overall dielectric constant of an interconnection line of the semiconductor integrated circuit device 1 and improves a resistance-capacitance (RC) delay.

In the exemplary embodiment shown in FIG. 1, a stack layer of a HDP layer 451 and a PETEOS layer 452 is sequentially deposited. Here, the HDP layer 451 and the PETEOS layer 452 are usually formed using a plasma deposition process. Here, the HDP layer 451 and the PETEOS layer 452 are formed by plasma deposition. Plasma deposition is beneficial in that deposition can be performed at low temperature. Although VUV rays may be irradiated when using plasma, the first VUV blocking layer 440 absorbs the radiated VUV rays, thereby preventing the semiconductor integrated circuit device 1 from being damaged by the irradiated VUV rays.

The via 463 is formed in predetermined region of the first intermetallic insulating layer 450 and electrically connects the first interconnection 430 and the second interconnection 420. The first via 463 may be formed of metallic material such as e.g., copper, titanium, or tungsten. In addition, the second barrier layer 462 is formed around the second vias 493 so that the material used in forming the first via 463 can be prevented from diffusing into the first intermetallic insulating layer 450.

The second interconnection 470 is formed on the first intermetallic insulating layer 450 and is electrically connected to the first interconnection 430. The second interconnection 470 can be formed of aluminum. The second intermetallic insulating layer 480 is formed on the second interconnection 470 and made of a low-dielectric constant insulating material. The second vias 493 are formed in a predetermined region of the second intermetallic insulating layer 480 and electrically connect the second interconnection 470 and the third interconnection 495. The passivation layer 496 is formed on the third interconnection 495 and passivates the semiconductor integrated circuit device 1.

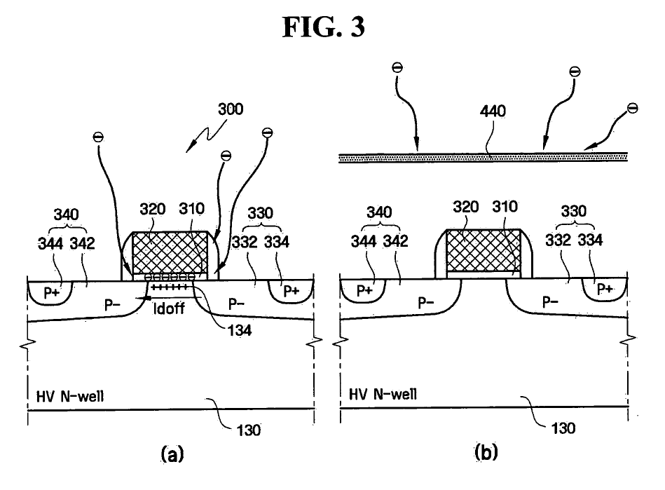

FIGS. 3A and 3B illustrate the effect of a semiconductor integrated circuit device of FIG. 1. That is, FIG. 3A illustrates the case where the semiconductor integrated circuit device has no diffusion-preventing metallic pattern, and FIG. 3B illustrates the case where the semiconductor integrated circuit device has a diffusion-preventing metallic pattern.

Referring to FIG. 3A, external ions or water included in a plurality of intermetallic insulating layers (see 450 and 480 of FIG. 2) is diffused so that negative ions can be accumulated on the gate insulating layer 310 of the PMOS high-voltage driving transistor 300. If negative ions are accumulated on the gate insulating layer 310, positive charges are accordingly accumulated on the gate insulating layer 310 so that an inversion layer 134 is formed. For instance, since the concentration of the N-well 130 of the PMOS high-voltage driving transistor 300 is low, the inversion layer 134 can be more easily formed. Thus, even when a voltage that is more than the threshold voltage is not applied to the gate interconnection 320, the drain off current Idoff can be generated.

On the other hand, referring to FIG. 3B, since external ions or water are prevented from penetrating into the gate insulating layer 310 by forming the diffusion-preventing metallic pattern 432a, negative ions are not accumulated on the gate insulating layer 310 of the PMOS high-voltage driving transistor 300.

Although only negative electric charges are described in FIG. 3 as being accumulated on the gate insulating layer 310, it is apparent to those skilled in the art that positive electric charges can also be accumulated by a substrate bias voltage applied to a semiconductor substrate. In addition, it is apparent to one skilled in the art that positive or negative ions can be accumulated in the NMOS high-voltage driving transistor as well.

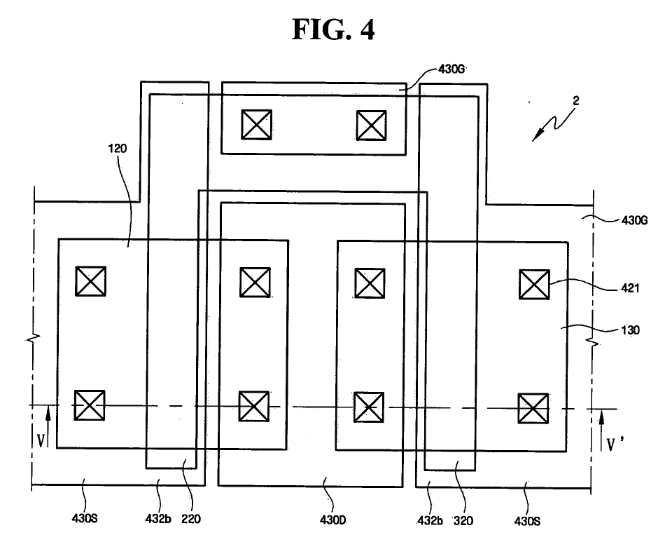

Semiconductor integrated circuit devices according to other exemplary embodiments of the present invention will now be described with reference to FIGS. 4 through 9. Components in these exemplary embodiments which are the same as the components referred to in the exemplary embodiment shown in FIGS. 1 through 2 will be identified with the same reference numerals, and their repetitive description will be omitted.

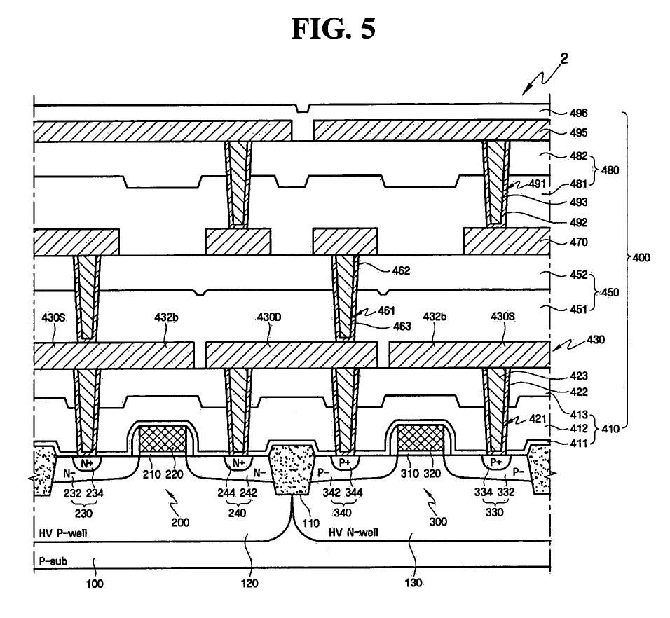

Referring to FIGS. 4 and 5, a semiconductor integrated circuit device 2 is different from the semiconductor integrated circuit device 1 shown in FIG. 1 in that a predetermined voltage is applied to a diffusion-preventing metallic pattern 432b. That is, the diffusion-preventing metallic pattern 432b is formed by extending the source voltage interconnection 430S for applying a source voltage to the source regions 230 and 330 of the NMOS and PMOS high-voltage driving transistors 200 and 300. Thus, the source voltage is applied to the diffusion-preventing metallic pattern 432b.

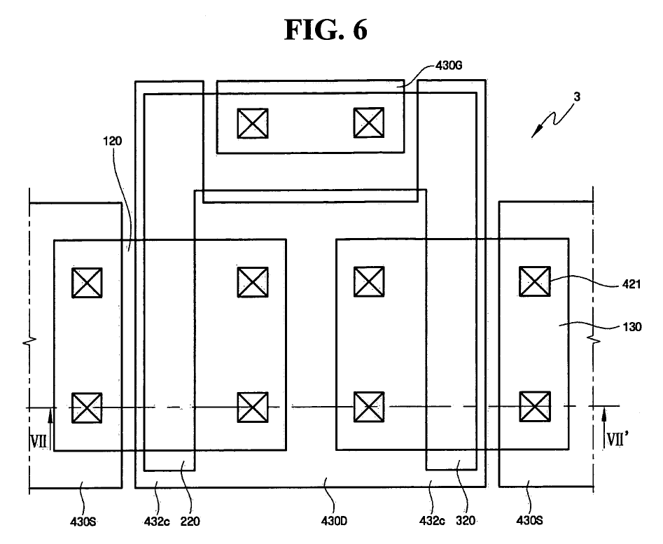

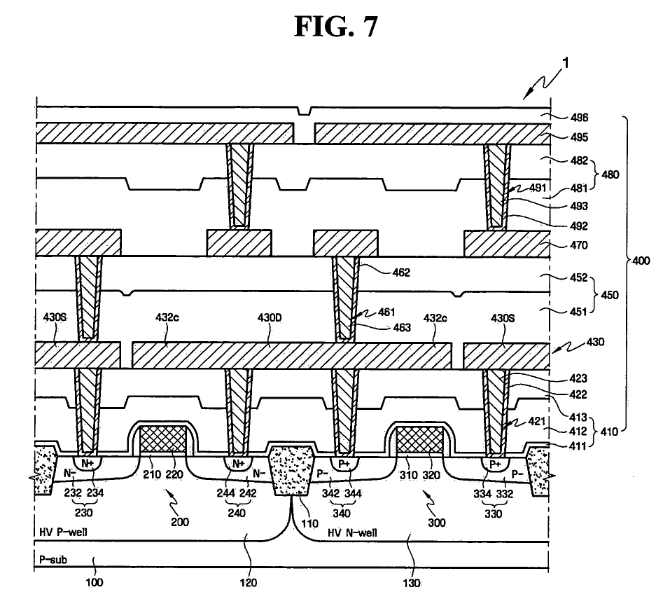

Referring to FIGS. 6 and 7, a semiconductor integrated circuit device 3 is different from the semiconductor integrated circuit device 1 shown in FIG. 1 in that a drain voltage is applied to a diffusion-preventing metallic pattern 432c. That is, the diffusion-preventing metallic pattern 432c is formed by extending the drain voltage interconnection 430D for applying a drain voltage to the drain regions 240 and 340 of the NMOS and PMOS high-voltage driving transistors 200 and 300. Thus, the drain voltage is applied to the diffusion-preventing metallic pattern 432c.

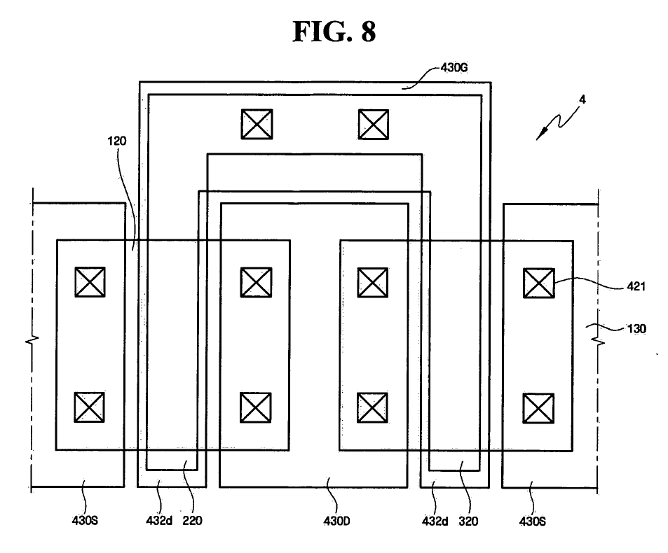

Referring to FIG. 8, a semiconductor integrated circuit device 4 is different from the semiconductor integrated circuit device 1 shown in FIG. 1 in that a gate voltage is applied to a diffusion-preventing metallic pattern 432d. That is, the diffusion-preventing metallic pattern 432d is formed by extending the gate voltage interconnection 430G for applying a gate voltage to the gate interconnections 220 and 320 of the NMOS and PMOS high-voltage driving transistors 200 and 300. Thus, the gate voltage is applied to the diffusion-preventing metallic pattern 432d.

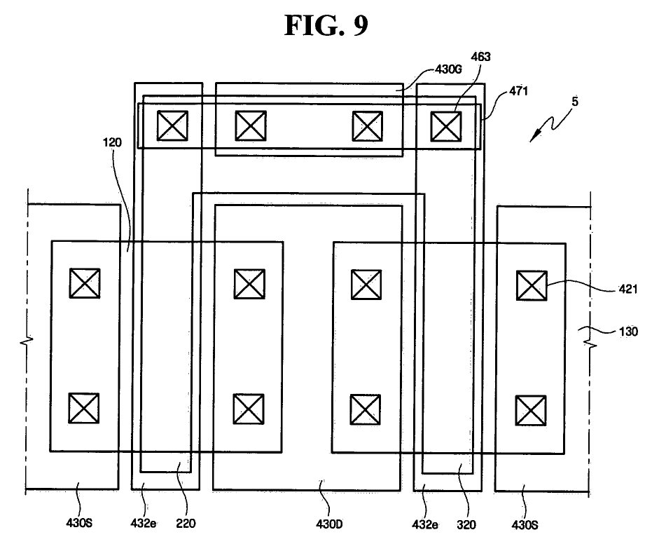

Referring to FIG. 9, a semiconductor integrated circuit device 5 is different from the semiconductor integrated circuit device 1 shown in FIG. 1 in that other voltage is applied to a diffusion-preventing metallic pattern 432e. That is, a predetermined voltage is applied to the diffusion-preventing metallic pattern 432e using a voltage interconnection 471 formed to the same interconnection level as the second interconnection (see 470 of FIG. 2). Reference numeral 463 denotes a first via for electrically connecting the diffusion-preventing metallic pattern 432e and the voltage interconnection 471.

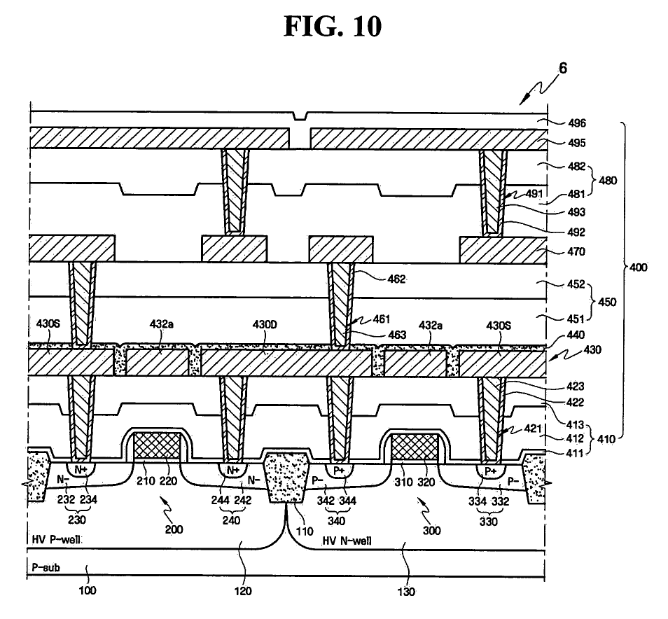

FIG. 10 is a cross-sectional view of a semiconductor integrated circuit device 6 according to another exemplary embodiment of the present invention. Like reference numerals are used into refer to elements in this exemplary embodiment which are the same as the elements of the exemplary embodiment shown in FIG. 2, and a repetitive description thereof will thus be omitted.

Referring to FIG. 10, the semiconductor integrated circuit device 6 includes a first interconnection 430, a diffusion-preventing metallic pattern 432a, an ILD layer 410, and a nitride layer 440 formed on substantially the entire surface of the ILD layer 410. The nitride layer 440 prevents external ions or water from penetrating into the semiconductor substrate 100. Thus, the nitride layer 440 is further formed so that the effect of preventing external ions or water can be increased. The nitride layer 440 can use an silicon nitride (SiN) layer or a silicon oxynitride (SiON) layer but is not limited to this. Here, the SiN layer has the effect of preventing external ions or water compared to the SiON layer and thus can be formed to a thickness more than 50 Å, and the SiON layer can be formed to a thickness more than 500 Å. However, it is apparent to one skilled in the art that the above dimensions may be changed. In addition, the thicker the SiN layer and the SiON layer, the larger the effect is of preventing external ions or water. However, the thickness of the SiN layer and the SiON layer can be adjusted according to characteristics of the semiconductor integrated circuit device.

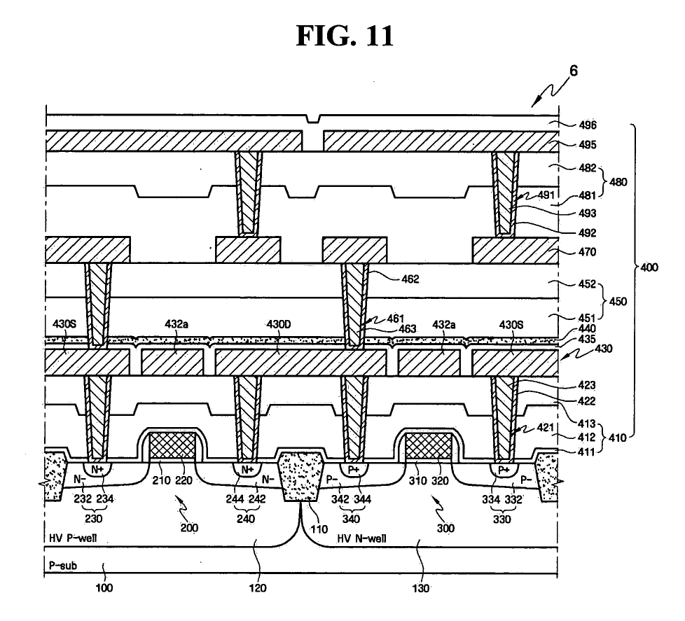

FIG. 11 is a layout diagram of a semiconductor integrated circuit device 7 according to another exemplary embodiment of the present invention. Like reference numerals are used to refer to elements in this exemplary embodiment which are the same as the elements of the exemplary embodiment shown in FIG. 10, and a repetitive description thereof will thus be omitted.

Referring to FIG. 11, the semiconductor integrated circuit device 7 includes a first interconnection 430, a diffusion-preventing metallic pattern 432a, an ILD layer 410, a nitride layer 440, and an oxide layer 435 interposed between the ILD layer 410 and the nitride layer 440. The oxide layer 435 serves as a buffer between the first interconnection 430, the diffusion-preventing metallic pattern 432a, the entire surface of the ILD layer 410, and the nitride layer 440. In addition, the oxide layer 435 is made of a material having a large gap-fill effect so that the space between the first interconnection 430 and the diffusion-preventing metallic pattern 432a can be sufficiently filled.

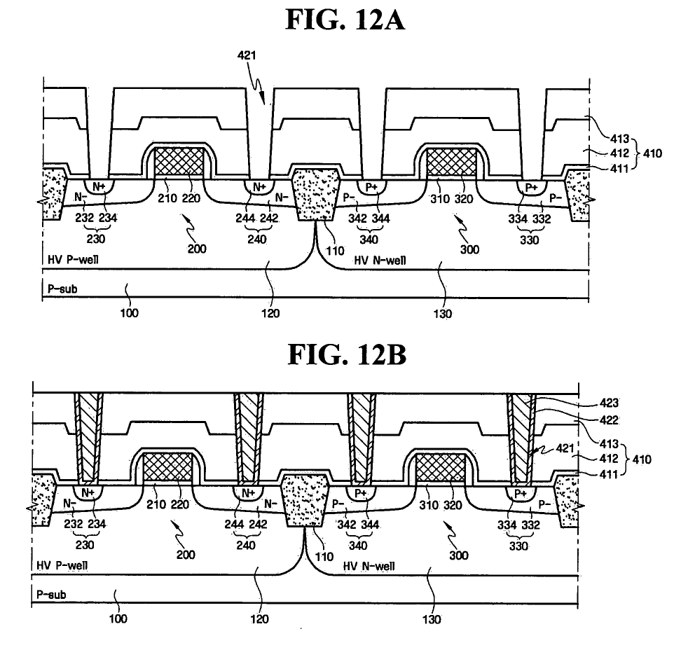

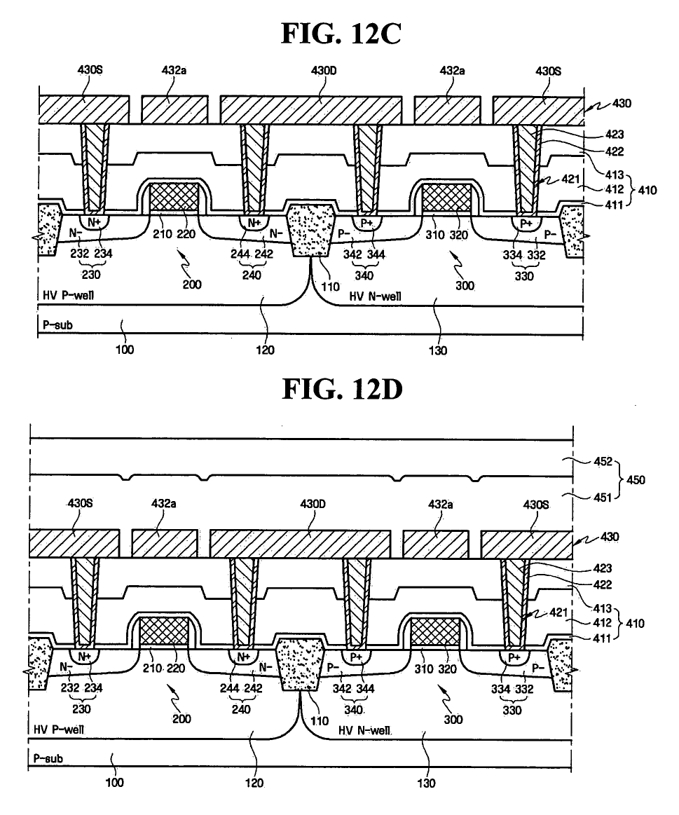

FIGS. 12A through 12D are cross-sectional views for explaining a method of fabricating the semiconductor integrated circuit device illustrated in FIG. 1.

Referring to FIG. 12A, a semiconductor substrate 100 is prepared. An isolation layer 110 is formed on the semiconductor substrate 100, thereby defining an active region. The NMOS high-voltage driving transistor 200 and the PMOS high-voltage driving transistor 300 are respectively formed on the active region.

Subsequently, the ILD layer 410 is formed on the NMOS and PMOS high-voltage driving transistors 200 and 300 and the semiconductor substrate 100. The ILD layer 410 may be made of a low-dielectric constant insulating material, and the PEOX layer 411, the BPSG layer 412, and the PETEOS layer 413 are sequentially formed.

Next, contact holes 421 through which the source/drain regions 230 and 240 of the NMOS high-voltage driving transistor 200 and the source/drain regions 330 and 340 of the PMOS high-voltage driving transistor 300 are exposed are formed between the ILD layers 410.

Referring to FIG. 12B, a first barrier layer 440 is formed along a profile formed on side and bottom surfaces of the contact holes 421 and a top surface of the ILD layer 410. The first barrier layer 440 may be formed of e.g., titanium (Ti), titanium nitride (TiN), titanium/titanium nitride (Ti/TiN), tantalum (Ta), tantalum nitride (TaN), tantalum/tantalum nitride Ta/TaN, or tantalum/titanium/titanium nitride (Ta/TiN) using chemical vapor deposition (CVD) or sputtering.

Subsequently, a metallic layer is formed by depositing a conductive material such as e.g. copper (Cu), titanium (Ti), or tungsten (W) on the first barrier layer 440 so as to sufficiently fill the contact holes 421. Here, it is preferable that Ti or W be deposited using CVD or sputtering because Cu is likely to be diffused to the interlayer dielectric layer 410.

Next, the metallic layer and the first barrier layer 440 are polished using chemical mechanical polishing (CMP) until the surface of the ILD layer 410 is exposed, thereby forming a contact 423 for filling the contact holes 421. At this time, the first barrier layer 440 remains as a first barrier layer pattern 422 on a sidewall and a bottom surface of the contact 423.

Referring to FIG. 12C, a conductive layer for a first interconnection is deposited on the ILD layer 410 and patterned, thereby simultaneously forming the first interconnection 430 and the diffusion-preventing metallic pattern 432a. Here, aluminum is used for the first interconnection line conductive layer and is deposited using CVD or sputtering.

Moreover, when the first interconnection line 430 is an aluminum interconnection line, an adhesion film may be further formed of Ti/TiN between the first interconnection line 430 and the contact 423 to improve the adhesion between the first interconnection line 430 and the contact 423.

When the diffusion-preventing metallic pattern 432a is formed to the same interconnection level as the first interconnection 430, sophisticated patterning can also be required since the distance between the first interconnection 430 and the diffusion-preventing metallic pattern 432a is narrow. In this case, after the conductive layer for a first interconnection is deposited, an anti-reflected coating film made of Ti, TiN, or Ti/TiN preventing diffused reflection of aluminum during a photolithography process may be further formed. After that, the anti-reflected coating film, the conductive layer for the first interconnection, and an adhesive film are patterned, thereby completing the first interconnection 430 and the diffusion-preventing metallic pattern 432a.

Referring to FIG. 12D, the first intermetallic insulating layer 450 is formed on the first interconnection 430, the diffusion-preventing metallic pattern 432a, and the entire surface of the ILD layer 410. The first intermetallic insulating layer 450 may be a low dielectric constant dielectric material. In this exemplary embodiment of the present invention, the first intermetallic insulating layer 450 is formed by sequentially depositing the HDP layer 451 and the PETEOS layer 452. Although the first intermetallic insulating layer 450 may contain external ions or water, the diffusion-preventing metallic pattern 432a prevents the external ions or water from diffusing into the first intermetallic insulating layer 450, thereby improving the operating characteristic of the NMOS and PMOS high-voltage driving transistors 200 and 300.

Referring back to FIG. 2, a photoresist pattern is formed on the first intermetallic insulating layer 450, thereby forming first via holes 461 through which the first interconnection 430 is exposed. The second barrier layer 462 is formed along a profile formed on side and bottom surfaces of the first via holes 461 and a top surface of the ILD layer 410. Subsequently, a metallic layer is formed by depositing a conductive material such as Cu, Ti, or W on the first barrier layer 440 so as to sufficiently fill the first via holes 461. Next, the metallic layer and the second barrier layer 462 are polished using chemical mechanical polishing (CMP) until the surface of the first intermetallic insulating layer 450 is exposed, thereby forming first vias 463 for filling the first via holes 461.

The second interconnection 470 is formed on the first intermetallic insulating layer 450. Subsequently, the second intermetallic insulating layer 480, the second via holes 491, a third barrier layer patterns 492, and the second vias 493 are formed.

The third interconnection 495 is formed on the second intermetallic insulating layer 480, and the passivation layer 496 for passivating the semiconductor integrated circuit device is formed on the third interconnection 495.

The exemplary embodiments present invention will be described in detail through the following concrete experimental examples. However, the experimental examples are for illustrative purposes and other examples and applications can be readily envisioned by a person of ordinary skill in the art.

### Experimental Example

NMOS high-voltage driving transistors a, b, and c each having a width of 25 μm and a length of 4 μm were fabricated. However, a diffusion-preventing metallic pattern was not formed on the same interconnection level as a first interconnection. On the other hand, an NMOS high-voltage driving transistor d having a width of 100 μm and a length of 4 μm and NMOS high-voltage driving transistors e and f having a width of 25 μm and a length of 4 μm were fabricated, and a diffusion-preventing metallic pattern was formed on the same interconnection level as the first interconnection.

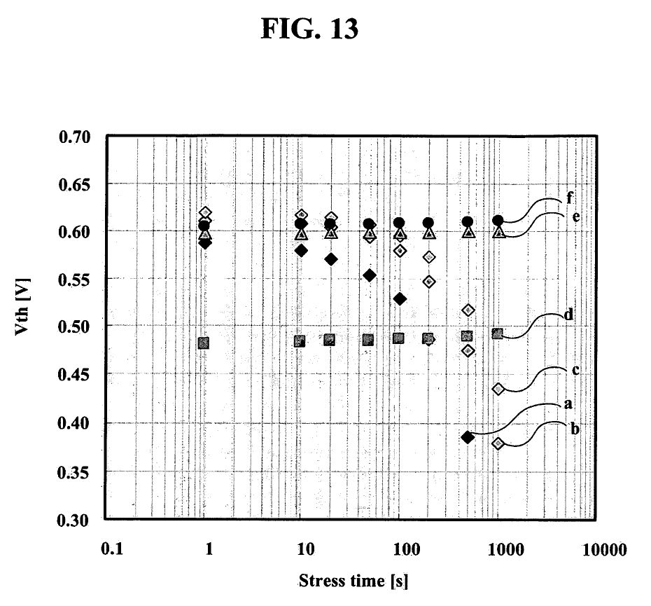

Subsequently, under the condition of thermal stress for 100° C. or higher, variations in threshold voltage Vth of the NMOS high-voltage driving transistors a to f were measured, and measurement results thereof are shown in FIG. 13.

Referring to FIG. 13, the x-axis represents a stress time, and the y-axis represents a threshold voltage Vth. In the NMOS high-voltage driving transistors a, b, and c without diffusion-preventing metallic pattern, the threshold voltage Vth starts to drop after 10 seconds. For example, in the NMOS high-voltage driving transistor b, a threshold voltage of about 0.61 V is maintained for about 10 seconds, gradually decreases after 10 seconds, and eventually has a threshold voltage of about 0.38 V at about 1000 seconds. If the threshold voltage decreases in this way, the leakage current Idoff increases.

On the other hand, in the NMOS high-voltage driving transistors d, e, and f with a diffusion-preventing metallic pattern, threshold voltages of about 0.48 V, 0.59 V, and 0.61 V, respectively, can be maintained at a constant level, even though the stress time increases.

A semiconductor integrated circuit device and method for fabricating the same in accordance with the exemplary embodiments of the present invention provides at least the following benefits set forth below.

First, external ions and water can be prevented from penetrating into the semiconductor substrate by forming the diffusion-preventing metallic pattern.

Second, operating characteristics of the semiconductor integrated circuit device can be improved by maintaining a threshold voltage at a constant level to reduce a drain off current Idoff.

What is claimed is:

1. A semiconductor integrated circuit device comprising:
a semiconductor substrate;
a transistor having a gate interconnection that extends in one direction on the semiconductor substrate and source/drain regions aligned in the gate interconnection and formed in the semiconductor substrate; and
a diffusion-preventing metallic pattern extending on the gate interconnection in the same direction as the gate interconnection to prevent diffusion of ions into the semiconductor substrate.

2. The semiconductor integrated circuit device of claim 1, wherein the diffusion-preventing metallic pattern is at substantially the same interconnection level as the first interconnection.

3. The semiconductor integrated circuit device of claim 2, wherein the diffusion-preventing metallic pattern is electrically floated.

4. The semiconductor integrated circuit device of claim 2, wherein a predetermined voltage is applied to the diffusion-preventing metallic pattern.

5. The semiconductor integrated circuit device of claim 4, wherein the first interconnection comprises a source voltage interconnection for applying a source voltage to the source region of the transistor, and the diffusion-preventing metallic pattern extends from the source voltage interconnection.

6. The semiconductor integrated circuit device of claim 4, wherein the first interconnection comprises a drain voltage interconnection for applying a drain voltage to the drain region of the transistor, and the diffusion-preventing metallic pattern extends from the drain voltage interconnection.

7. The semiconductor integrated circuit device of claim 4, wherein the first interconnection comprises a gate voltage interconnection for applying a gate voltage to the gate interconnection of the transistor, and the diffusion-preventing metallic pattern extends from the gate voltage interconnection.

8. The semiconductor integrated circuit device of claim 2, further comprising a nitride layer formed on the first interconnection and substantially an entire surface of the diffusion-preventing metallic pattern and which prevents ions from being diffused into the semiconductor substrate.

9. The semiconductor integrated circuit device of claim 8, further comprising an oxide layer formed between substantially an entire surface of the diffusion-preventing metallic pattern and the nitride layer.

10. The semiconductor integrated circuit device of claim 1, wherein the transistor is a high-voltage driving transistor.

11. The semiconductor integrated circuit device of claim 10, wherein the high-voltage driving transistor comprises the source/drain regions which are comprised of a lightly doped region and a highly doped region, the lightly doped region is aligned in the gate interconnection and formed in the semiconductor substrate and the lightly doped region is of a different conductive type from the semiconductor substrate and highly doped region, the highly doped region is separated a predetermined interval apart from the gate electrode, the highly doped region is formed shallower than the lightly doped region and is of a different conductive type from the semiconductor substrate.

12. A method of fabricating a semiconductor integrated circuit device, the method comprising:
forming a transistor having a gate interconnection that extends in one direction on a semiconductor substrate and source/drain regions aligned in the gate interconnection and formed in the semiconductor substrate; and
forming a diffusion-preventing metallic pattern extending on the gate interconnection in the same direction as the gate interconnection and which prevents ions from being diffused into the semiconductor substrate.

13. The method of claim 12, wherein the diffusion-preventing metallic pattern is formed to substantially the same interconnection level as the first interconnection.

14. The method of claim 13, wherein the diffusion-preventing metallic pattern is electrically floated.

15. The method of claim 13, wherein a predetermined voltage is applied to the diffusion-preventing metallic pattern.

16. The method of claim 15, wherein the first interconnection comprises a source voltage interconnection for applying a source voltage to the source region of the transistor, and the diffusion-preventing metallic pattern is formed by extending the source voltage interconnection.

17. The method of claim 15, wherein the first interconnection comprises a drain voltage interconnection for applying a drain voltage to the drain region of the transistor, and the diffusion-preventing metallic pattern is formed by extending the drain voltage interconnection.

18. The method of claim 15, wherein the first interconnection comprises a gate voltage interconnection for applying a gate voltage to the gate interconnection of the transistor, and the diffusion-preventing metallic pattern is formed by extending the gate voltage interconnection.

19. The method of claim 13, further comprising forming a nitride layer for preventing ions from being diffused into the semiconductor substrate on substantially an entire surface of the first interconnection and the diffusion-preventing metallic pattern after forming the diffusion-preventing metallic pattern.

20. The method of claim 19, further comprising forming an oxide layer on substantially an entire surface of the diffusion-preventing metallic pattern before forming the nitride layer.

21. The method of claim 12, wherein the transistor is a high-voltage driving transistor.

22. The method of claim 21, wherein the high-voltage driving transistor comprises the source/drain regions which are comprised of a lightly doped region and a highly doped region, the lightly doped region is aligned in the gate interconnection and formed in the semiconductor substrate, the lightly doped region is of a different conductive type from the semiconductor substrate and highly doped region, the highly doped region is separated a predetermined interval apart from the gate electrode, the highly doped region is formed shallower than the lightly doped region and is of a different conductive type from the semiconductor substrate.
